(19) United States
(12) Patent Application Publication
(10) Pub. No.: US 2002/0125501 A1
(43) Pub. Date: Sep. 12, 2002

(54) Integrated circuit

(76) Inventor: Andreas Dicks, Hamburg (DE)

Correspondence Address: U.S. Philips Corporation, 580 White Plains Road, Tarrytown, NY, 10591, US

(21) Appl. No.: 10/086,878

(22) Filed: Mar. 1, 2002

(30) Foreign Application Priority Data
Mar. 7, 2001 (DE) 10110778.1

(51) Int. Cl. H01L 31/072

(52) U.S. Cl. 257/200

(57) ABSTRACT

In an integrated circuit comprising a processor (1), a data memory (2) and function blocks (4,5) a first data bus is provided for the communication among them. Previous to a data transmission of large datasets, according to the invention a direct connection is provided between at least two function blocks (4,5) by way of a second data bus (6). One function block (4) then acts as master and one function block (5) as a slave. The slave has a linear address space which the function block (4) acting as master can access via a handshake method. In the function block (5) acting as a slave the linear address space is mapped onto a buffer memory.

The invention relates to a so-termed embedded system, which involves a system on an integrated circuit. Generally, such a system includes a processor, a data memory, and in some cases several function blocks. Besides, there is generally at least one data bus system via which the processor, the data memory and the function blocks can communicate with each other or via which data can be exchanged, respectively.

For special purposes it can sometimes be desirable that at least one of the function blocks exchange large volumes of data with another function block. In such a case, in state of the art systems there must be intermediate storage in the memory for large external datasets. In any case, due to the double data exchange via the general bus system of the embedded system, this embedded system is loaded considerably. If, for example, a large dataset is to be transferred from a source to a drain, the data are first placed in the memory via the data bus connected to it. In a subsequent step the data from this memory are once again transferred via the data bus from this memory to the drain. Thus the data bus is called upon two times.

The object of the invention is to provide an integrated circuit of the type mentioned in the opening paragraph in which a large dataset can be transferred between at least two function blocks without this repeatedly burdening the data bus connection between processor, data memory, and the other function blocks.

This object is achieved by the following characteristics features:

An integrated circuit comprising a processor, a data memory and function blocks, in which a data bus is provided for communication between the processor, the data memory and the function blocks, a logical direct connection on the data bus for a data transfer between at least two function blocks being provided via a handshake method with one function block acting as master and one function block acting as a slave, the latter having a linear address space, to which the function block acting as master can have access by way of the handshake method and which address space in the function block acting as a slave is mapped onto a buffer memory.

In this embedded system in terms of the invention is provided a logical direct connection via the available data bus over which the above mentioned large dataset can be immediately transferred between two function blocks without having to be buffered in a data memory. This direct connection is realized and carried out by means of a special handshake method specifically made for this connection.

According to the invention there is provided that one function block acts as master and one function block as a slave. The slave has a linear address space that the master can address directly via the second data bus. Thus by way of a simple form of data bus supported handshake method, driven by the master, a direct data transfer between master and slave can take place. The master then writes data in the linear address space or reads data directly from it. In the function block acting as a slave, the linear address space is shown on a buffer from which this function block, for its part, can read the data or write them in it. This buffer memory is thus addressable both by the master via the linear address space and by the second function block itself.

The course of reading or writing of data by the master is controlled via a simple handshake method which requires no particular effort on the part of the function blocks.

According to an embodiment of the invention as claimed in claim 2, the data bus is a standard bus system which is standardized for on-chip bus systems. In such systems this may be, for example, a PI-Bus or an AMBA-Bus. This offers the advantage that the function blocks acting as master, which are usually in any case suitable for the processing of such bus protocols, do not require special arrangement or modification for the existence of the direct connection according to the invention. The bus system architecture normally used for these function blocks may rather be used. In this embodiment of the invention there is therefore no considerable additional circuitry for the data bus on the part of the function blocks which communicate with each other or exchange data via this direct connection. The bus protocol may be a standard protocol of the respectively provided bus system.

According to another embodiment of the invention as claimed in claim 3, the buffer provided for the function block acting as a slave is a so-termed ping-pong buffer onto which the address space is cyclically mapped. Such ping-pong memories are at least in two parts, with in each case one part being addressable via the data bus via the linear address space and another part being addressable by the function block acting as a slave. In this constellation the function block acting as master can write data in the first part of the memory or read data from it, whereas the function block acting as a slave can read data from or write them in the second part of the memory. If both memory areas have been processed, then the allocation of the two parts of the ping-pong buffer is reversed, so that now the function block acting as master can access in the second part of the memory and the function block acting as a slave can access in the first part of the memory. This offers the advantage that both function blocks can access the buffer memory simultaneously, even though in different parts thereof, which, however, means no significant limitation.

Further embodiments of the invention as claimed in claims 4 and 5 involve embodiments of the handshake method in which the function block acting as master and the function block acting as a slave can communicate directly via the direct connection. The proposed orders or acknowledge messages are predefined by the bus system of the data bus.

The layout of the integrated circuit according to the invention can be used advantageously particularly for such function blocks that deliver or receive large datasets. For example, this circuit can be advantageously provided as another embodiment as claimed in claim 6 for a JPEG-Coder/Encoder (CODEC) which delivers large datasets specifically, for example, a coded image, to a function block acting as a slave, specifically a memory interface of a mass storage. The function block acting as a slave, is a memory interface which has a memory or ping-pong buffer. The interface receives the data of the JPEG-CODEC via the ping-pong buffer and delivers these datasets, for its part to an external memory medium which may, for example, be a Flash-ROM-memory card or a hard disk.

These and other aspects of the invention are apparent from and will be elucidated with reference to the embodiments described hereinafter.

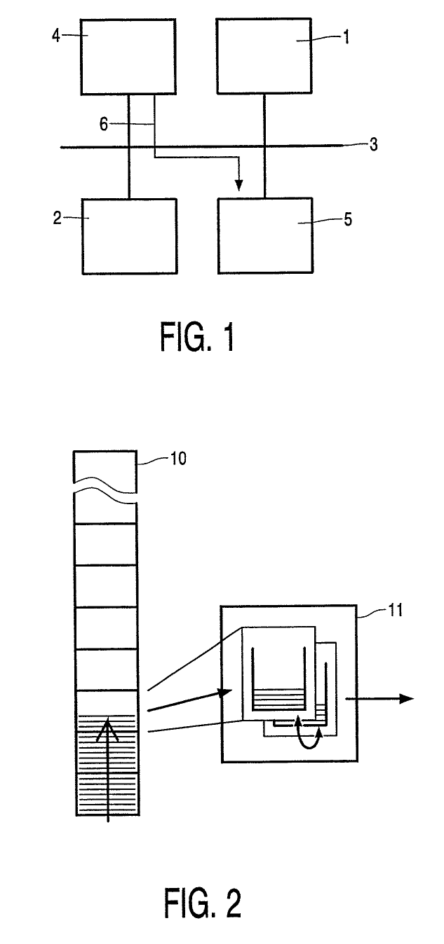

FIG. 1 shows a block circuit diagram of an integrated circuit according to the invention,

FIG. 2 gives a diagrammatic representation of the linear address space and the ping-pong buffer in a function block acting as a slave of the system as shown in FIG. 1,

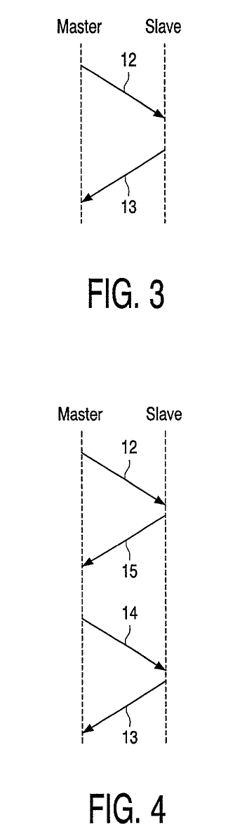

FIG. 3 gives a diagrammatic representation of a handshake routine of the direct connection of two function blocks of the system as shown in FIG. 1, and

FIG. 4 shows a handshake routine as per FIG. 3, in which the function block acting as a slave is basically not ready for data reception.

A block circuit diagram shown in FIG. 1 shows a so-termed embedded system, that is to say, a system realized on an integrated circuit, which shows a processor 1 and a memory 2. The processor 1 can access the memory 2 via a data bus 3 and write data therein or read them from it.

In addition, in the illustration as shown in FIG. 1, there are two other function blocks 4 and 5, which are also connected to the data bus 3. Of course further function blocks are possible as well.

The processor 1, the memory 2 and the function blocks 4 and 5 communicate via the data bus 3 or exchange data via this data bus, respectively.

If desired, single data blocks can write or read, respectively large datasets, which would then be a relatively heavy load on the first data bus 3 if the data had to be buffered in the memory 2, since then a writing and reading process would be required.

In the example of embodiment shown in FIG. 1, for example, one should assume that with respect to function block 4 this is a JPEG-CODEC, which encodes images and thus provides relatively large datasets. These data should be delivered to the second function block 5, which is, for example, a memory interface.

In systems according to the state of the art, this data exchange via a data bus 3 would take place by way of the data first being written in the memory 2 by the functional block 4. In a second step, the data would then be transferred from the memory 2 to the function block 5. The data bus 3 would then be burdened twice with the entire dataset.

To avoid this excessive load of the data bus 3, according to the invention a logical direct connection 6 is made, which takes place in terms of hardware via the data bus 3. This direct connection 6 connects in the example of embodiment shown in FIG. 1 the first function block 4 and the second function block 5 with each other, enabling a direct data exchange via the data bus 3 between the function blocks 4 and 5 and bypassing the memory 2.

The data bus system 3 is preferably a standard data bus system as is used for on-chip systems and is also standardized. This has the advantage that the function blocks are usually already prepared for this data bus system, so that due to the existence of the direct connection, no additional circuitry need to be included in the function blocks, because the handshake method required for the direct connection is based on the data bus protocol.

According to the invention, one of the function blocks acts as master and one as a slave. In the example of embodiment, the function block 4 acts as master and the function block 5 as a slave.

In the simple handshake method, which takes place between the two function blocks involved in the data exchange via the second data bus, the function block acting as master 4 controls the routines.

In the function block 5 acting as a slave there is a buffer which can be addressed via a linear address space via the data bus 3. This buffer is preferably a ping-pong buffer which will be elucidated in more detail later on.

The function block 4 acting as master can thus directly access the buffer via the direct connection 6 over the data bus 3, via the linear address space in the function block 5 acting as a slave. The function block 4 can thus directly read data from the buffer or write them in it. It goes without saying that also the function block 5 acting as a slave can directly read data from this buffer or write them in it.

Thus, in this relatively easy manner, direct data exchange between the function blocks 4 and 5 is possible, without the need to expand their architecture to any significant extent.

It should be stressed that the direct connection 6 shown in FIG. 1 shows a logical connection that is realized in terms of hardware via the data bus 3.

FIG. 2 is a diagrammatic representation of the linear address space and the buffer in the second function block 5 acting as a slave as shown in FIG. 1. As already stated above, the buffer in the function block 5 acting as a slave can advantageously be arranged as a ping-pong buffer. This is shown in FIG. 2 as a ping-pong buffer 11.

Such a ping-pong buffer has at least two memory areas, which can be addressed alternately, externally via the linear address space 10, which is shown in FIG. 2, or internally by the function block in which the ping-pong buffer 11 is provided.

For an actual routine, this means, for example, that a first memory area of the ping-pong buffer 11 is first of all addressable via the linear address space 10 by an external function block that acts as master. Thus this function block can write data in the first memory area of the ping-pong buffer 11 or read them from it. Simultaneously, the second memory area is assigned to the function block in which the ping-pong buffer 11 is located and can be addressed by this, so that this function block can write data in this second memory area or read them from it.

Once the data in both memory areas have been processed, the allocation of the memory areas is exchanged. Now, via the external linear address space 10, the second memory area can be accessed and also via the function block which includes a ping-pong buffer 11. Once these memory areas have been processed, the allocation of the memory areas is once again exchanged.

Through this relatively simple technique, simultaneous access to the ping-pong buffer is possible for both the external function block acting as master and the function block accommodating the ping-pong buffer 11.

As already stated above, the data exchange of the function block 4 acting as master and the function block 5 acting as a slave as shown in FIG. 1 is processed by means of the logical direct connection 6 via a simple handshake method.

In FIGS. 3 and 4 there are diagrammatic representations which permit a simple processing of data exchange via the direct connection taking place via data bus 3 by means of a handshake method in the system as shown in FIG. 1.

The representation of FIG. 3 diagrammatically shows a master and a slave; here, for example, it concerns function blocks 4 and 5, respectively, of the representation as shown in FIG. 1.

In accordance with the representation shown in FIG. 3, the function block acting as master first sends a selection signal 12 to the slave. If the slave is ready to receive, that is to say, wishes to permit the function block acting as master to access the linear address area, the slave or the function block acting as a slave, respectively, sends an acknowledge message 13 to the master or to the function block acting as master. As soon as the master receives this acknowledge message, it knows that the slave is ready to receive or transmit and commences receiving or transmitting data; thus the data exchange via the direct connection 6 of the system as shown in FIG. 1 commences.

FIG. 4 contains a similar situation to FIG. 3, but here the slave, after a selection signal 12 by the master, is not ready to transmit or receive. So first of all it transmits an abort-try again acknowledge message 15. This message signals the master that the slave is not ready to transmit or receive and that the master should try again to transmit. The master transmits a new selection signal 16 to the slave. Now the slave is ready to transmit or receive and transmits an acknowledge message 13 to the master. Now the data transfer as shown in FIG. 3 can commence.

Such handshake mechanisms are present in standard bus systems, such as, for example, the PI-Bus or the AMBA-Bus. Since most function blocks are after all capable of processing such bus protocols, the direct connection and the handshake method used for this purpose does not call for any additional circuitry in the function blocks. But simultaneously the advantage is realized that the data bus 3 of the illustration shown in FIG. 1 is burdened by the data exchange only once. This is very important when large quantities of data must be exchanged between two function blocks, as is the case, for example, with a JPEG-CODEC.

1. An integrated circuit comprising a processor (1), a data memory (2) and function blocks (4,5), in which a data bus (3) is provided for communication between the processor (1), the data memory (2) and the functional blocks (4,5), a logical direct connection on the data bus for a transfer of data between at least two function blocks (4, 5) being provided via a handshake method, with one function block (4) acting as master and one function block (5) acting as a slave, the latter having a linear address space to which the function block (4) acting as master can have access by way of the handshake method and which address space in the function block (5) acting as a slave is mapped onto a buffer memory.

2. An integrated circuit as claimed in claim 1, characterized in that, the data bus (6), on which the handshake method takes place, is a standard bus system that is standardized for on-chip bus systems.

3. An integrated circuit as per claim 1, characterized in that, the buffer memory is a ping-pong buffer (11), onto which the address space is cyclically mapped.

4. An integrated circuit as claimed in claim 1 or 2, characterized in that, in the handshake method the function block (5) acting as a slave, sends an acknowledge message (13) to the function block (4) acting as master, after each permitted and finalized access of the function block acting as master to the linear address ranges.

5. An integrated circuit as claimed in claim 1 or 2, characterized in that, in the handshake method the function block (5) acting as a slave sends an abort-try again acknowledge message (15) to the function block (4) acting as master after each rejected access of the function block (4) acting as master to the linear address ranges.

6. An integrated circuit as claimed in claim 1, characterized in that, in the function block (4) acting as master is a JPEG-CODEC and the function block (5) acting as a slave is a memory interface which access an externally provided storage medium.
